(19) United States
(12) Patent Application Publication
(10) Pub. No.: US 2007/0017698 A1
(43) Pub. Date: Jan. 25, 2007

(54) Multilayer printed wiring board fabrication method and multilayer printed wiring board

(75) Inventor: Yukihiro Ueno, Hiroshima (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/488,013

(22) Filed: Jul. 18, 2006

(30) Foreign Application Priority Data
Jul. 19, 2005 (JP) 2005-208570

(51) Int. Cl. H05K 1/11

(52) U.S. Cl. 174/258; 174/262; 174/266; 29/852

(57) ABSTRACT

An inner printed wiring board is provided with an inner insulating resin layer, an inner circuit pattern, and an inner via land. In order for the inner via land to make an interlayer connection, a pattern form for making a connection, unlike an ordinary wiring pattern, is adopted. The inner circuit pattern is formed with the same formation method and form as an ordinarily formed wiring pattern. The inner via land adopts a form having an inner window portion in which an inner conducting layer was removed during formation.

### BACKGROUND OF THE INVENTION

This application claims priority under 35 U.S.C. § 119(a) on Patent Application No. 2005-208570 filed in Japan on Jul. 19, 2005, the entire contents of which are hereby incorporated by reference.

The present invention relates to fabrication methods for a multilayer printed wiring board that has two or more conducting layers and has an interlayer connecting layer that makes a connection between conducting layers, and multilayer printed wiring boards.

### DESCRIPTION OF THE RELATED ART

A conventional multilayer printed wiring board fabrication method will be described based on FIGS. 14 to 20.

FIGS. 14 to 20 are schematic cross-sectional diagrams of a multilayer printed wiring board that illustrate a conventional multilayer printed wiring board fabrication method. Also, relevant portions are shown enlarged in FIGS. 16 to 20.

FIG. 14 shows a cross-section of an inner printed wiring board in which an inner circuit pattern has been formed.

In order to produce a multilayer printed wiring board 100 (see FIG. 15), first, a double-sided circuit board (an inner printed wiring board 110) that constitutes the inner layer of the multilayer printed wiring board 100 is prepared. The inner printed wiring board 110 includes an inner insulating resin layer 111, and an inner circuit pattern 113 and an inner via land 114 that are formed on the surface of the inner insulating resin layer 111. The shape of the connection pattern of the inner via land 114 differs from the inner circuit pattern 113 in order to make a good connection (electrical connection) with an outer printed wiring board 120 (see FIG. 15).

The inner circuit pattern 113 and the inner via land 114 are formed by etching (patterning), with a suitable pattern, copper foil (an inner conducting layer) that has been layered (formed) on the surface of the inner insulating resin layer 111. There may also be instances when, as necessary, a through-hole that becomes an inner via hole is provided in advance in the inner insulating resin layer 111 (not shown).

FIG. 15 shows a multilayer printed wiring board in a state in which an outer printed wiring board has been layered on an inner printed wiring board.

The outer printed wiring board 120 that constitutes an outer layer of the multilayer printed wiring board 100 is layered on both sides of the inner printed wiring board 110. The multilayer printed wiring board 100 is formed by layering (forming) an outer insulating resin layer 121 and an outer conducting layer 122 in order on the inner printed wiring board 110. Ordinarily, the outer printed wiring board 120 is formed by layering (affixing) a resin board (the outer insulating resin layer 121) in a semi-hardened state, commonly called a prepreg, and copper foil (the outer conducting layer 122) on the inner printed wiring board 110 with pressure and heat.

Other than the above, as methods of forming the outer insulating resin layer 121 and the outer conducting layer 122, methods are known such as a method in which a semi-hardened resin board called an RCC (Resin Coated Copper), with copper foil affixed in advance, is layered, and a method in which on both sides of the inner printed wiring board 110, print formation of resin (the outer insulating resin layer 121) is performed and also a conductor (the outer conducting layer 122) is formed by plating.

In FIG. 16, the relevant portions of a multilayer printed wiring board in a preparation stage in which a via hole is formed are shown enlarged.

An outer via land layer 124 is formed by patterning (etching and removing) outer conducting layer 122, which is a portion that corresponds to the region in which it is desired to connect to the inner via land 114, i.e., a via hole 130 (see FIG. 17). That is, the outer via land layer 124 is formed with a pattern shape having an outer window portion 125 positioned in the inner via land 114.

When the outer conducting layer 122 is formed by plating, a method is also possible in which the outer conducting layer 122 is formed in advance as a portion that is not plated when plating is performed.

In FIG. 17, the relevant portions of a multilayer printed wiring board in a state in which a via hole has been formed are shown enlarged.

By using the outer via land layer 124 as a mask, and irradiating a laser beam, for example a carbon dioxide gas laser beam or a YAG (Yttrium Aluminum Garnet) laser beam on the multilayer printed wiring board 100, and forming a hole that corresponds to the outer window portion 125, the via hole 130 is formed. The portion in which the outer via land layer 124 (copper foil) has been formed is not processed with a laser beam, but because the outer insulating resin layer 121, which is a region exposed corresponding to the outer window portion 125, is removed, the via hole 130 can be formed.

In a stage at which the inner via land 114 has been exposed, processing with the laser beam is stopped, and the via hole 130 is formed from the outer via land layer 124 reaching to the inner via land 114. This sort of hole forming method is ordinarily known as a conformal mask method. In order to appropriately irradiate the laser beam, ordinarily another mask is placed corresponding to the multilayer printed wiring board 100.

In FIG. 18, the relevant portions of a multilayer printed wiring board in a state in which entire face panel plating has been executed are shown enlarged.

Suitable preprocessing is executed on the multilayer printed wiring board 100 in which the via hole 130 has been formed, and entire face panel plating is performed, forming a panel plating conducting layer 131 as an interlayer conducting layer on the entire face (surface) of the multilayer printed wiring board 100. The panel plating conducting layer 131 is also formed in the via hole 130, so the inner via land 114 and the outer layer 124 are connected to each other.

In FIG. 19, the relevant portions of a multilayer printed wiring board in a state in which an outer circuit pattern has been formed are shown enlarged.

By performing appropriate panel etching (patterning) in the panel plating conducting layer 131, an outer later circuit pattern 123, a via land connecting portion 132, and an outer via land 126 are formed. With the via land connecting portion 132, an interlayer connection is made between the inner via land 114 and the outer via land 126 in a state with independent patterns.

Afterward, the multilayer printed wiring board 100 is completed as a complete board via post processing such as solder resist formation, symbol formation, surface processing, and dimension processing.

The multilayer printed wiring board fabrication method shown in FIGS. 14 to 19 is a processing method referred to as a laser via hole processing method.

As described above, a carbon dioxide gas laser or YAG laser is often used for laser via hole processing. This processing method is basically a method in which insulating resin is burned and removed with laser energy, and in many cases, residual material 140 (see FIG. 20) such as unprocessed insulating resin or alternatively carbonized insulating resin or reinforced fiber remains in the bottom face of the via hole, impairing the reliability of the via hole connection.

FIG. 20 is a relevant portion enlarged cross-sectional view that shows the structure of the periphery of the interlayer connecting layer of a multilayer printed wiring board that illustrates a problem with a multilayer printed wiring board fabricated with a conventional laser via hole processing method.

Essentially, residual material 140 such as carbonized insulating resin or reinforced fiber remains on the surface of the inner via land 114, which must be completely exposed, and the via land connecting portion 132 that has been formed by panel plating is only partially connected to the inner via land 114.

Accordingly, a problem occurs that an expected low connection resistance cannot be obtained. The cause of this is that when heat stress or mechanical stress is received, the interface of the inner via land 114 and the via land connecting portion 132 may peel away, and further, the via land connecting portion 132 of the surface of the residual material 140 is damaged, and there is a high probability of via hole destruction, breaking, a poor connection, or the like, thus hindering reliability.

On the other hand, there is a risk that continuing irradiation of the laser beam until the insulating resin of the bottom face of the via hole 130 (see FIG. 16) is completely removed will damage the inner via land 114 exposed to the bottom face of the via hole 130 and the inner insulating resin layer 111, and control and adjustment of the laser beam become difficult.

Ordinarily, measures such as desmearing or soft etching are taken to deal with the problems in the conventional laser via hole processing.

Desmearing is a method in which residual material remaining on the inner via land, including the interior walls of the via hole, is removed with a strong alkaline chemical solution or plasma. However, with this method, there is the problem that the outer insulating resin layer is damaged, and physical properties, in particular strength and insulation properties, are lowered.

Soft etching is a method in which, by thinly removing by dissolving the inner via land of the bottom face of the via hole with a soft etching solution, residual material remaining on the inner via land is removed. However, with this method, it is difficult to control the thickness of the inner via land conductor formed on the bottom face of the via hole, and there are unavoidably cases in which remaining material widely covers the inner via land on the bottom face of the via hole, and moreover there is the problem that in the case of a high-density wiring pattern, the etching solution can not adequately permeate a via hole that has been formed with a small diameter.

Methods have been proposed (for example, see JP 2002-198653A, JP 2002-237680A, JP 2003-31957A, JP 2003-503832A, JP H11-195853A, JP H11-330310A, and JP 2004-146711), for example, in which processing is performed in advance on reinforced fiber or the like included in an insulating resin layer, and in which a weave, thickness and shape for the reinforced fiber are devised, and in which laser processability is improved, but none of these methods is flawless, and there is also the problem that preprocessing of material such as reinforced fiber takes time and money.

Also, a method has been proposed in which the laser processability of the resin insulation layer in the vicinity of the bottom face of the via hole is increased (for example, see JP H11-266068), but besides the fact that providing a resin layer with good laser processability itself leads to an increase in man-hours and material, ordinarily this sort of material has a weaker heat tolerance than a conventional interlayer insulating resin, and when heat stress has been received, besides the danger of bringing about interlayer separation, there is a problem such as impairing the mechanical properties of the board.

### SUMMARY OF THE INVENTION

The present invention was made in view of such circumstances, and it is an object thereof to provide a fabrication method for a multilayer printed wiring board having multiple wiring layers and a multilayer printed wiring board, in which by providing a through hole (an inner window portion) in an inner via land provided corresponding to a via hole formed in order to make a connection between an inner conducting layer and an outer conducting layer, residual material is not generated on the bottom face of the via hole.

A fabrication method for a multilayer printed wiring board according to the present invention includes forming an inner via land on the surface of an inner insulating resin layer, and layering an outer insulating resin layer that covers the inner via land on the inner insulating resin layer, and forming an outer via land layer having an outer window portion whose position is matched to that of the inner via land on the surface of the outer insulating resin layer, and forming a via hole that exposes the inner via land by removing the outer insulating resin layer that corresponds to the outer window portion using the outer via land layer as a mask, and forming an interlayer connecting layer that connects the exposed inner via land and the outer via land layer, in which when forming the inner via land, an inner window portion that passes through the inner via land is formed, and the via hole is formed by laser processing.

In the fabrication method for a multilayer printed wiring board according to the present invention, a bottom face of the via hole is positioned in the inner window portion.

In the fabrication method for a multilayer printed wiring board according to the present invention, the bottom face of the via hole is positioned in the inner insulating resin layer.

In the fabrication method for a multilayer printed wiring board according to the present invention, a flat face of the inner via land is exposed to the bottom face of the via hole.

In the fabrication method for a multilayer printed wiring board according to the present invention, an edge face of the inner window portion is exposed to a side face of the via hole.

In the fabrication method for a multilayer printed wiring board according to the present invention, an inner circuit pattern is formed when forming the inner via land.

In the fabrication method for a multilayer printed wiring board according to the present invention, the inner insulating resin layer and the outer insulating resin layer are formed from epoxy resin, polyimide resin, polyether ketone resin, polyester resin, or liquid crystal polymer resin.

In the fabrication method for a multilayer printed wiring board according to the present invention, the inner insulating resin layer and the outer insulating resin layer include fiber cloth or nonwoven cloth.

In the fabrication method for a multilayer printed wiring board according to the present invention, the laser processing is performed with a carbon dioxide gas laser or a YAG laser.

In the fabrication method for a multilayer printed wiring board according to the present invention, the processes in claim 1 are repeated.

The multilayer printed wiring board according to the present invention is provided with an inner insulating resin layer, an inner via land formed on the surface of the inner insulating resin layer, an outer insulating resin layer that covers the inner via land on the inner insulating resin layer, an outer via land having an outer window portion whose position is matched to that of the inner via land formed on the surface of the outer insulating resin layer, a via hole formed such that it corresponds to the outer window portion and passes through the outer insulating resin layer, and a via land connecting portion that is formed in the via hole and connects the outer via land and the inner via land, and the inner via land has an inner window portion that passes through the inner via land.

In the multilayer printed wiring board according to the present invention, the processing speed with laser processing is slower for the inner insulating resin layer than for the outer insulating resin layer.

In the multilayer printed wiring board according to the present invention, the inner insulating resin layer includes a resin layer for which laser processing is difficult, and a resin layer for which laser processing is easy, formed between the resin layer for which laser processing is difficult and the inner via land.

In the multilayer printed wiring board according to the present invention, the resin layer for which laser processing is difficult and the resin layer for which laser processing is easy include reinforced fiber, and the density of the reinforced fiber is larger for the resin layer for which laser processing is difficult than for the resin layer for which laser processing is easy.

In the multilayer printed wiring board according to the present invention, the density of the reinforced fiber is adjusted by the area of openings in the weave of the reinforced fiber.

In the multilayer printed wiring board according to the present invention, the density of the reinforced fiber is adjusted by the thickness of the reinforced fiber.

In the multilayer printed wiring board according to the present invention, the resin layer for which processing is difficult includes reinforced fiber, and the resin layer for which processing is easy does not include reinforced fiber.

In the multilayer printed wiring board according to the present invention, the inner insulating resin layer has a metal foil layer at an inside position that corresponds to the inner window portion, and a flat face of the metal foil layer is exposed to the bottom face of the via hole.

In the multilayer printed wiring board according to the present invention, the inner insulating resin layer has a concave portion corresponding to the inner window portion.

In the multilayer printed wiring board according to the present invention, an edge face of the inner window portion is exposed to a side face of the via hole, and the edge face and the via land connecting portion are connected.

With the multilayer printed wiring board fabrication method and multilayer printed wiring board according to the present invention, because the inner window portion in which a conductor is not present is formed in the inner via land positioned on the bottom face of the via hole, exposing the inner insulating resin layer, when performing the laser processing that forms the via hole, it is possible to insure processing as far as a position deeper than the conducting surface of the inner via land, and so it is possible to effectively remove residual material that hinders the connection of the inner via land and the outer via land, or impairs the reliability of the connection.

According to the multilayer printed wiring board fabrication method and multilayer printed wiring board according to the present invention, because the inner window portion in which a conductor is not present is formed in the inner via land positioned on the bottom face of the via hole, exposing the inner insulating resin layer, an effect is exhibited in which, when performing the laser processing that forms the via hole, it is possible to insure processing as far as a position deeper than the conducting surface of the inner via land.

Accordingly, is it possible to reduce or eliminate residual material that hinders the connection of the inner via land and the outer via land, or impairs the reliability of the connection. That is, an effect is exhibited in which, using a conventional configuration and processing method without change, it is possible to avoid a decrease in the reliability of the via hole connection due to residual material being attached to the conducting surface of the inner via land.

### BRIEF DESCRIPTION OF THE DRAWINGS

FIG. 1 is a schematic cross-sectional diagram of a multilayer printed wiring board that illustrates the fabrication method of a multilayer printed wiring board according to Embodiment 1 of the present invention.

FIG. 2 is a schematic cross-sectional diagram of a multilayer printed wiring board that illustrates the fabrication method of a multilayer printed wiring board according to Embodiment 1 of the present invention.

FIG. 3 is a schematic cross-sectional diagram of a multilayer printed wiring board that illustrates the fabrication method of a multilayer printed wiring board according to Embodiment 1 of the present invention.

FIG. 4 is a schematic cross-sectional diagram of a multilayer printed wiring board that illustrates the fabrication method of a multilayer printed wiring board according to Embodiment 1 of the present invention.

FIG. 5 is a schematic cross-sectional diagram of a multilayer printed wiring board that illustrates the fabrication method of a multilayer printed wiring board according to Embodiment 1 of the present invention.

FIG. 6 is a schematic cross-sectional diagram of a multilayer printed wiring board that illustrates the fabrication method of a multilayer printed wiring board according to Embodiment 1 of the present invention.

FIG. 7 is a schematic cross-sectional diagram of a multilayer printed wiring board that illustrates the fabrication method of a multilayer printed wiring board according to Embodiment 1 of the present invention.

FIG. 8 is a schematic cross-sectional diagram of a multilayer printed wiring board that illustrates the fabrication method of a multilayer printed wiring board according to Embodiment 1 of the present invention.

FIG. 9 is a schematic cross-sectional diagram of a multilayer printed wiring board that illustrates a modified example of a via hole in a fabrication process of a multilayer printed wiring board according to Embodiment 2 of the present invention.

FIG. 10 is a schematic cross-sectional diagram of a multilayer printed wiring board that illustrates a modified example of a via hole in a fabrication process of a multilayer printed wiring board according to Embodiment 2 of the present invention.

FIG. 11 is a schematic cross-sectional diagram of a multilayer printed wiring board that illustrates a modified example of a via hole in a fabrication process of a multilayer printed wiring board according to Embodiment 2 of the present invention.

FIG. 12 is a schematic cross-sectional diagram of a multilayer printed wiring board that illustrates a modified example of a via hole in a fabrication process of a multilayer printed wiring board according to Embodiment 2 of the present invention.

FIG. 13 is a schematic cross-sectional diagram of a multilayer printed wiring board that illustrates a modified example of a via hole in a fabrication process of a multilayer printed wiring board according to Embodiment 2 of the present invention.

FIG. 14 is a schematic cross-sectional diagram of a multilayer printed wiring board that illustrates the fabrication method of a multilayer printed wiring board according to the conventional technology.

FIG. 15 is a schematic cross-sectional diagram of a multilayer printed wiring board that illustrates the fabrication method of a multilayer printed wiring board according to the conventional technology.

FIG. 16 is a schematic cross-sectional diagram of a multilayer printed wiring board that illustrates the fabrication method of a multilayer printed wiring board according to the conventional technology.

FIG. 17 is a schematic cross-sectional diagram of a multilayer printed wiring board that illustrates the fabrication method of a multilayer printed wiring board according to the conventional technology.

FIG. 18 is a schematic cross-sectional diagram of a multilayer printed wiring board that illustrates the fabrication method of a multilayer printed wiring board according to the conventional technology.

FIG. 19 is a schematic cross-sectional diagram of a multilayer printed wiring board that illustrates the fabrication method of a multilayer printed wiring board according to the conventional technology.

FIG. 20 is a schematic cross-sectional diagram of a multilayer printed wiring board that illustrates the fabrication method of a multilayer printed wiring board according to the conventional technology.

### DESCRIPTION OF THE PREFERRED EMBODIMENTS

Hereinafter, embodiments of the present invention will be described with reference to the accompanying drawings.

### Embodiment 1

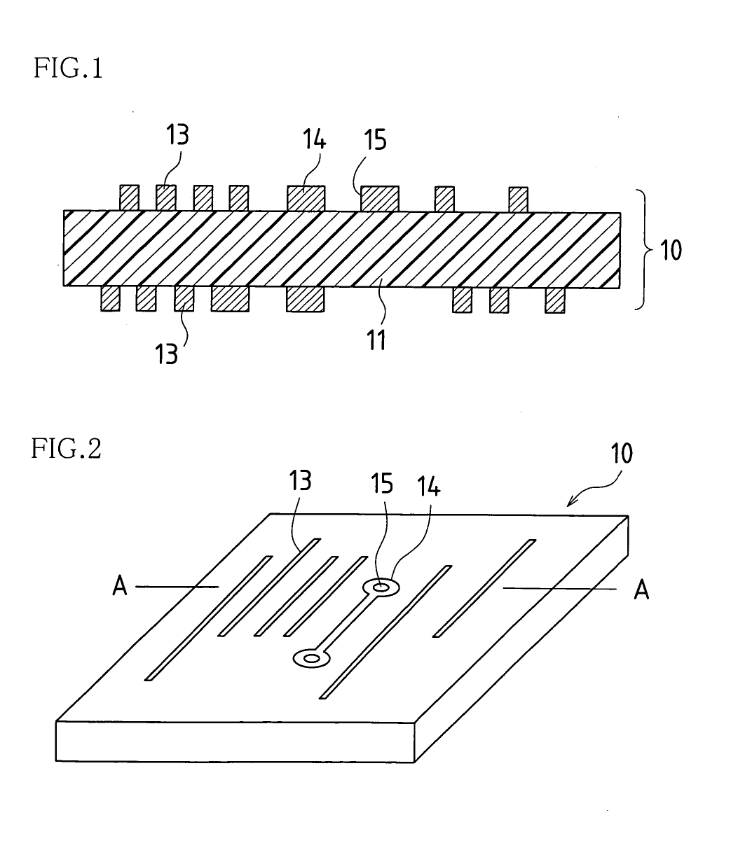

The fabrication method of a multilayer printed wiring board according to Embodiment 1 of the present invention will be described with reference to FIGS. 1 to 8.

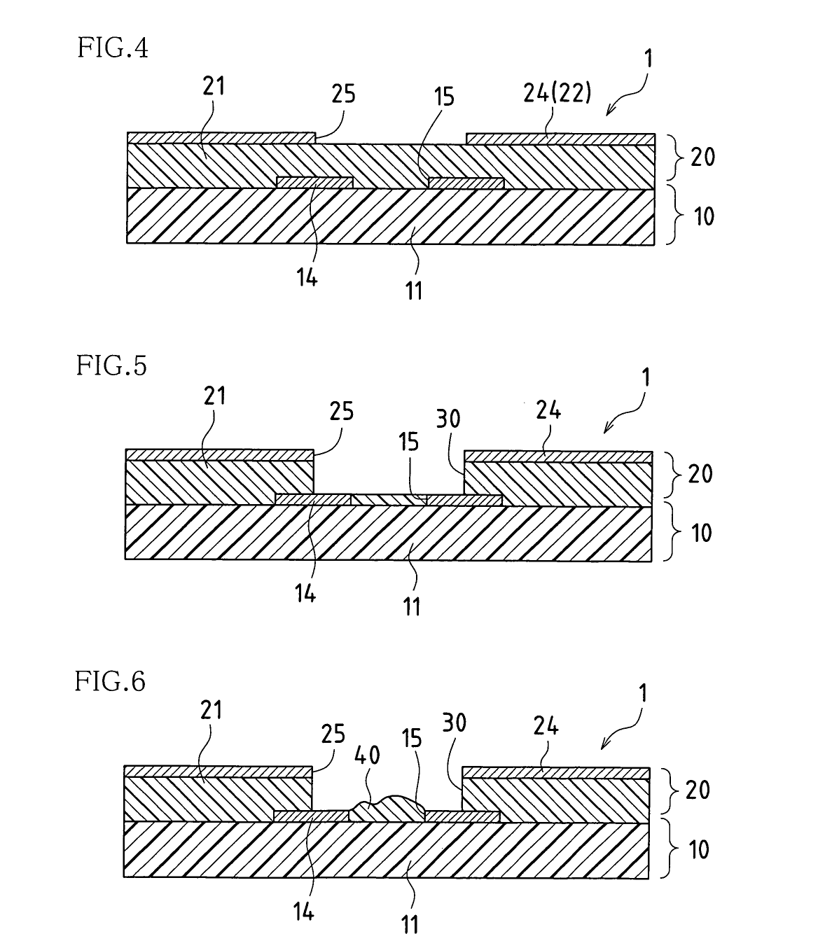

FIGS. 1 to 8 are schematic cross-sectional diagrams of a multilayer printed wiring board that illustrates the fabrication method of a multilayer printed wiring board according to Embodiment 1 of the present invention. In FIGS. 4 to 8, relevant portions are shown enlarged.

FIG. 1 shows a cross-section of an inner printed wiring board in which an inner circuit pattern has been formed. This is a cross-section along reference letters A-A of the inner printed wiring shown in FIG. 2.

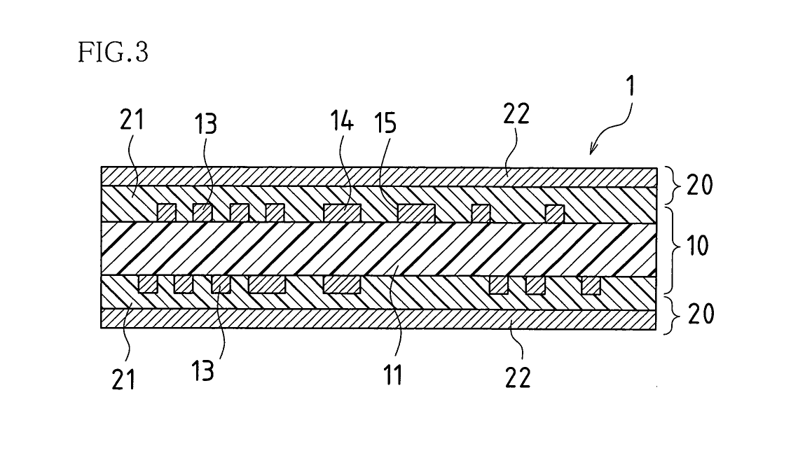

A two-sided wiring board (an inner printed wiring board 10) that becomes an inner core material for fabricating a multilayer printed wiring board 10 (see FIG. 3) is prepared. Basically equal to an “inner core” initially prepared in the fabrication process of, for example, an ordinary multilayer board or built-up multilayer wiring board, or alternatively a multilayer flexible wiring board or compound multilayer wiring board, in this two-sided wiring board, hole processing (not shown) necessary for an inner via hole has been performed using publicly known technology on material in which a conducting layer (for example, copper foil)(inner conducting layer) has been formed on both sides of an insulating resin board/film (an inner insulating resin layer 11), a circuit pattern (an inner circuit pattern 13 and an inner via land 14) have been formed, and plating has been performed.

That is, the inner printed wiring board 10 is provided with the inner insulating resin layer 11, the inner circuit pattern 13, and the inner via land 14. In order to make an interlayer connection, the inner via land 14 has a pattern shape for making a connection, unlike an ordinary wiring pattern.

As the insulating resin layer of the inner insulating resin layer 11, for example, a fiberglass-reinforced epoxy resin board is used, but other than this, the inner insulating resin layer 11 may also be configured with a synthetic resin such as an epoxy resin that is not fiberglass-reinforced, polyimide resin, polyether ketone resin, aramid resin, or liquid crystal polymer resin. The inner insulating resin layer 11 may also be further reinforced by including fiber cloth or nonwoven cloth.

FIG. 2 shows a perspective view of the inner printed circuit board in FIG. 1.

The inner circuit pattern 13 is formed with the same method and shape as an ordinarily formed circuit pattern. On the other hand, the inner via land 14 is formed with a shape having an inner window portion 15, in which the inner conducting layer was removed during formation. That is, the inner window portion 15, is formed as a through-hole that passes through the inner via land 14 in the layering direction, so it has a shape in which the inner insulating resin layer 11 is exposed in the inner window portion 15. By adding a modification to a pattern mask (for example, an etching mask) that forms (patterns) the inner circuit pattern 13 and the inner via land 14 (outer periphery), it is possible to form the inner window portion 15 at the same time as the inner circuit pattern 13 and the inner via land 14 without adding any new processes.

FIG. 3 shows the multilayer printed wiring board in a state in which an outer printed wiring board has been layered on the inner printed wiring board.

An outer printed wiring board 20 that constitutes an outer of the multilayer printed wiring board 1 is layered on both sides of the inner printed wiring board 10 shown FIGS. 1 and 2. The outer printed wiring board 20 can be formed in the same manner as an ordinary multilayer wiring board. That is, it is formed by a method such as layering an outer insulating resin layer 21 and an outer conducting layer 22 on both sides of the inner printed wiring board 10, printing, and laminating. In the present embodiment, using commercially available material known as RCC in which copper foil has been layered on insulating material that is an epoxy resin base in a semi-hardened state, after layering, heat and pressure were applied, and the RCC material was affixed to the inner printed wiring board 10 and hardened.

FIG. 4 shows an enlarged view of the relevant portions of a multilayer printed wiring board in a preparatory stage in which a via hole is formed. In FIGS. 4 to 8, as stated above, mainly the relevant portions (the via hole) related to the present embodiment are shown.

An etching resist is formed and applied to the outer conducting layer 22, and using this as an etching mask, by removing portions of the outer conducting layer 22 that will become a via hole 30 (see FIG. 5), an outer via land layer 24 is formed that has an outer window portion 25 whose position is matched to the inner via land 14. The edge portion of the inner peripheral side of the outer window portion 25 can be set to range from the edge portion of the inner peripheral side of the inner window portion 15 to the edge portion of the outer peripheral side of the inner via land 14. The outer window portion 25 is formed as a through-hole that passes through the outer via land layer 24, so in the outer window portion 25, the outer insulating resin layer 21 is exposed.

FIG. 5 shows an enlarged view of relevant portions of a multilayer printed wiring board in a state in which a via hole has been formed.

By using the outer via land layer 24 as a mask and irradiating a laser beam, for example a carbon dioxide gas laser beam or a YAG laser beam, the outer insulating resin layer 21 that corresponds to the outer window portion 25 and is exposed is removed. This laser processing is performed until the inner via land 14 is exposed, and thus the via hole 30 is formed.

The procedure for processing and forming the via hole 30 using a laser beam is known as a laser beam processing method, and the method of using the outer conducting layer 22 (the outer via land layer 24) as a mask for forming a hole is known as a conformal mask method.

In the present embodiment, on the surface of the inner via land 14 that becomes the bottom face of the via hole 30, the inner conducting layer of a region near the center where remaining material 40 (see FIG. 6) is most likely to be produced is removed, forming the inner window portion 15.

In the laser processing, due to laser processing advancing until (that flat face of) the inner via land 14 is exposed to the bottom face of the via hole 30, processing is stopped in the region where the inner via land 14 is present, but in the region that corresponds to the inner window portion 15, from shortly before the laser processing reaches this depth, effects due to laser processing such as heat will steadily occur.

That is, in the region that corresponds to the inner window portion 15, laser processing steadily advances to a location that is deeper than the surface level of the inner via land 14, and at the point in time that the laser processing reaches the level of the bottom face of the via hole 30 (the level of the surface of the inner via land 14), due to the bottom face of the via hole 30 being positioned in the inner window portion 15 (in the range of the conductor in the direction of thickness of the inner via land 14), resin is removed without producing residual material or scorching even in the region that corresponds to the inner window portion 15, and it is possible to obtain a clean bottom face for the via hole 30.

FIG. 6 shows an enlarged view of relevant portions of a multilayer printed wiring board in a state in which residual material was produced when forming the via hole.

Even assuming that in the region that corresponds to the inner window portion 15, the resin of the outer insulating resin layer 21 is not completely removed, and carbonized residual material has been left in the center portion as the residual material 40, on the bottom face of the via hole 30, because it is difficult for the residual material 40 to remain on the surface of the inner via land 14, when heat stress or the like as in the conventional example has been received, it is rare that separation occurs in the interface of the inner via land 14 and the residual material 40, or that the interlayer connection (a via land connecting portion 32: see FIG. 8) is broken in the via hole 30.

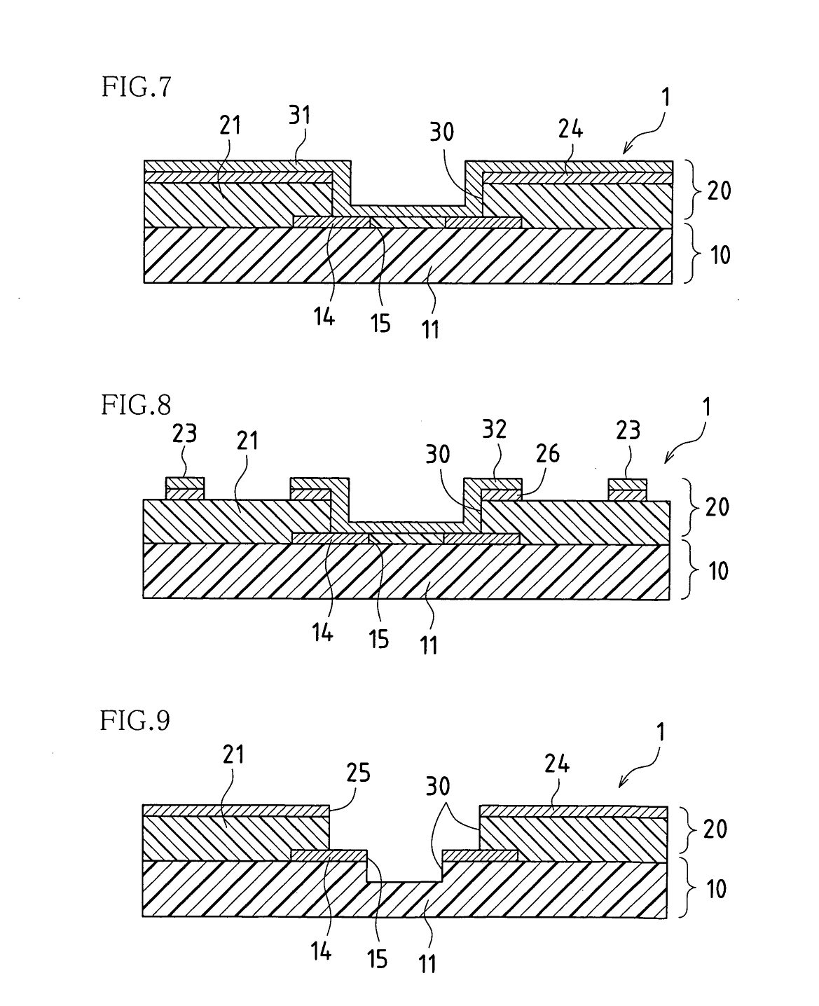

FIG. 7 shows an enlarged view of relevant portions of a multilayer printed wiring board in a state in which entire face panel plating has been executed.

Appropriate preprocessing is executed on the multilayer printed wiring board 1 in which the via hole 30 was formed, and entire face panel plating is performed, forming a panel plating conducting layer 31 as an interlayer connecting layer on the entire face (surface) of the multilayer printed wiring board 1. Because the panel plating conducting layer 31 is also formed in the via hole 30, the inner via land 14 and the outer via land layer 24 are connected to each other.

FIG. 8 shows an enlarged view of relevant portions of a multilayer printed wiring board in a state in which an outer circuit pattern has been formed.

By performing appropriate pattern etching (patterning) on the panel plating conducting layer 31, an outer circuit pattern 23, a via land connecting portion 32, and an outer via land 26 are formed. In interlayer connection is made between the inner via land 14 and the outer via land 26 in a state with independent patterns by the via land connecting portion 32.

Afterward, through post-processing such as solder resist formation, symbol formation, surface processing, and dimension processing, the multilayer printed wiring board is completed as a complete board.

In the present embodiment, a four-layer wiring board using a two-sided wiring board as the inner printed wiring board 10 was disclosed, but the present invention is not limited to this configuration, and can also be applied to a multilayer printed wiring board having two layers or three layers. Also, by repeating the processes and configuration disclosed in the present embodiment, it is possible to apply the present invention to a multilayer printed wiring board having five or more layers.

The multilayer printed wiring board according to the present embodiment is applicable to a multilayer printed wiring board in which comparatively high wiring density is sought, such as that used in high performance electronic equipment.

### Embodiment 2

The multilayer printed wiring board disclosed in the present embodiment employs basically the same configuration and processes as the multilayer printed wiring board disclosed in Embodiment 1, but various modifications are made to the depth or form of the via hole in the laser processing.

The fabrication method of the multilayer printed wiring board according to Embodiment 2 of the present invention will be described with reference to FIGS. 9 to 13.

FIGS. 9 to 13 are schematic cross-sectional diagrams of a multilayer printed wiring board that illustrate modified examples of the via hole in the fabrication process of the multilayer printed wiring board according to Embodiment 2 of the present invention. As in FIGS. 4 to 8, relevant portions are shown enlarged.

FIG. 9 shows a state in which laser processing was performed such that the bottom face of the via hole is positioned inside of the inner insulating resin layer.

In the present example, compared to Embodiment 1, laser processing time is lengthened and laser strength is increased, and the via hole is set further into the inner insulating resin layer 11 from the inner window portion 15 of the inner via land 14. That is, the inner insulating resin layer 11 has a concave portion that corresponds to the inner window portion 15.

With this configuration, the conducting surface of the inner via land 14 is processed by the laser beam with adequate cleanliness, and residual material is not left on the bottom face of the via hole 30, so the connection with the outer via land layer 24 is reliably fixed. That is, because the via hole 30 encroaches as far as the inner insulating resin layer 11, the connection strength of the via land connecting portion 32 via the via hole 30 improves, yielding advantages such as improving reliability.

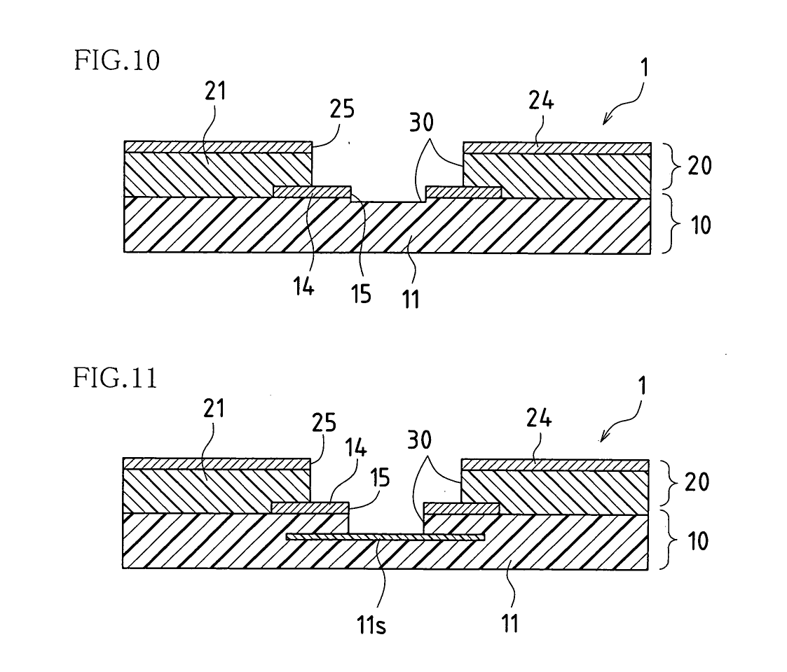

FIG. 10 shows a state in which laser processing was performed by more precisely controlling adjustment of the position of the bottom face of the via hole.

This example discloses a method in which, when laser processing the via hole 30, it is possible to better control the timing at which laser processing is stopped.

A configuration is adopted in which the quality of the material of the inner insulating resin layer 11 and the outer insulating resin layer 21 is changed so that the processing speed due to laser processing is slower for the inner insulating resin layer 11 than the outer insulating resin layer 21, or alternatively in which processing is difficult, so the via hole 30 is stopped at the surface of the inner insulating resin layer 11 or the vicinity thereof.

For example, combinations are possible such as modified acrylic resin for the outer insulating resin layer 21 and epoxy resin for the inner insulating resin layer 11, or alternatively, epoxy resin for the outer insulating resin layer 21 and fiberglass-reinforced epoxy resin for the inner insulating resin layer 11 (that is, a case in which the easily processed resin layer does not include reinforced fiber, and the resin layer that is difficult to process includes reinforced fiber).

When the inner insulating resin layer 11 and the outer insulating resin layer 21 are constituted from the same material, when laser processing is unnecessarily strong or is continued for a long time, there is a risk that the via hole 30 will pass through the inner insulating resin layer 11 and have an effect on the inner conductor on the opposite side or the outer insulating resin layer 21, but according to present example, even if there is some variation in the processing time or processing strength, a via hole 30 with a fixed, correct depth is obtained.

FIG. 11 shows a state in which laser processing was performed by more precisely controlling adjustment of the position of the bottom face of the via hole.

In the present example, as in the case of FIG. 10, a method is disclosed in which, when laser processing the via hole 30, it is possible to better control the timing at which laser processing is stopped. That is, in the present example, the inner insulating resin layer 11 is formed from a resin layer for which laser processing is difficult, disposed at a predetermined depth (position), and a resin layer for which laser processing is easy, disposed between the resin layer for which laser processing is difficult and the inner via land 14.

Ordinarily, the inner insulating resin layer 11 is fabricated by layering a plurality of semi-hardened resin boards, but in this case, at the position desired for the bottom face of the via hole 30 (the position corresponding to the inner window portion 15), a material layer 11s that is difficult to process, such as copper foil or other metal foil, is sandwiched.

With this configuration, when performing laser processing, processing of the via hole 30 finishes at the position of the material layer 11s that is difficult to process, and the bottom face is decided.

Even if the material layer 11s that is difficult to process is not sandwiched, a method is also possible in which reinforced fiber included within the inner insulating resin layer 11 is used. That is, because laser processing is difficult for reinforced fiber such as glass or aramid usually included in the inner insulating resin layer 11 for the sake of maintaining dimensional precision and strength, by performing adjustment by relatively increasing the density of reinforced fiber at the position desired for the bottom face of the via hole 30 (the position that corresponds to the inner window portion 15), it is possible to easily control the depth of the bottom face of the via hole 30.

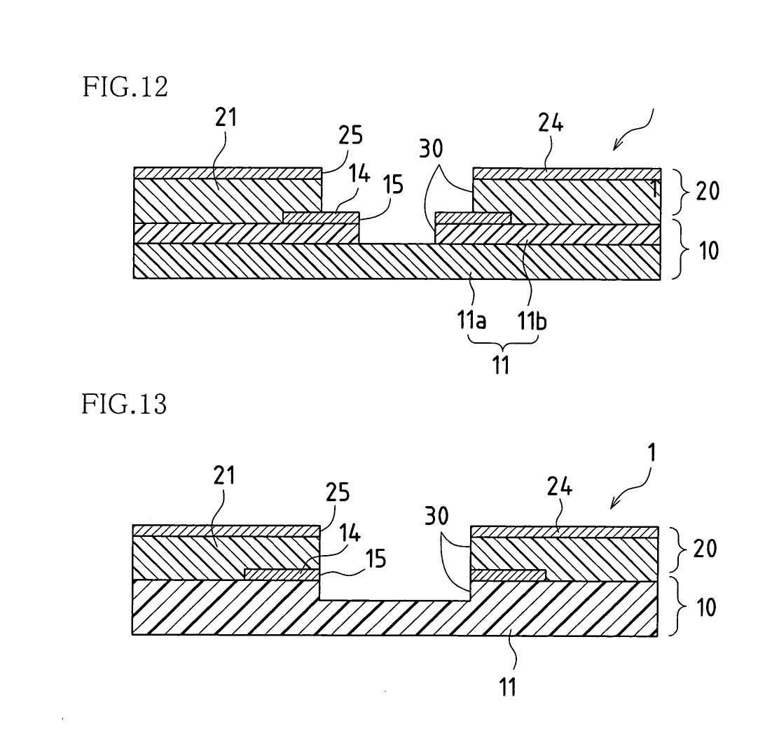

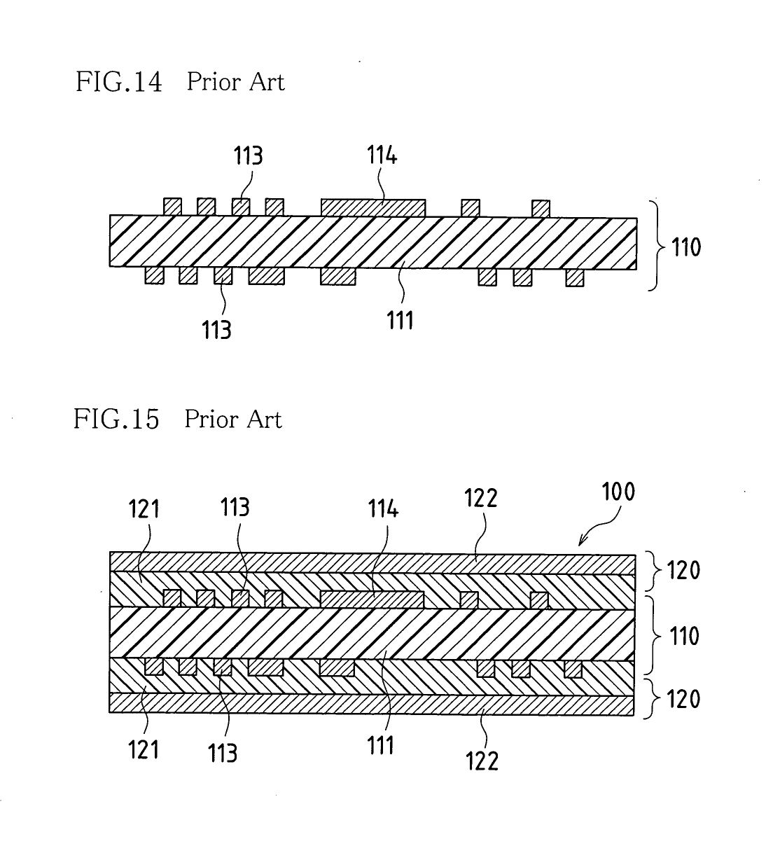

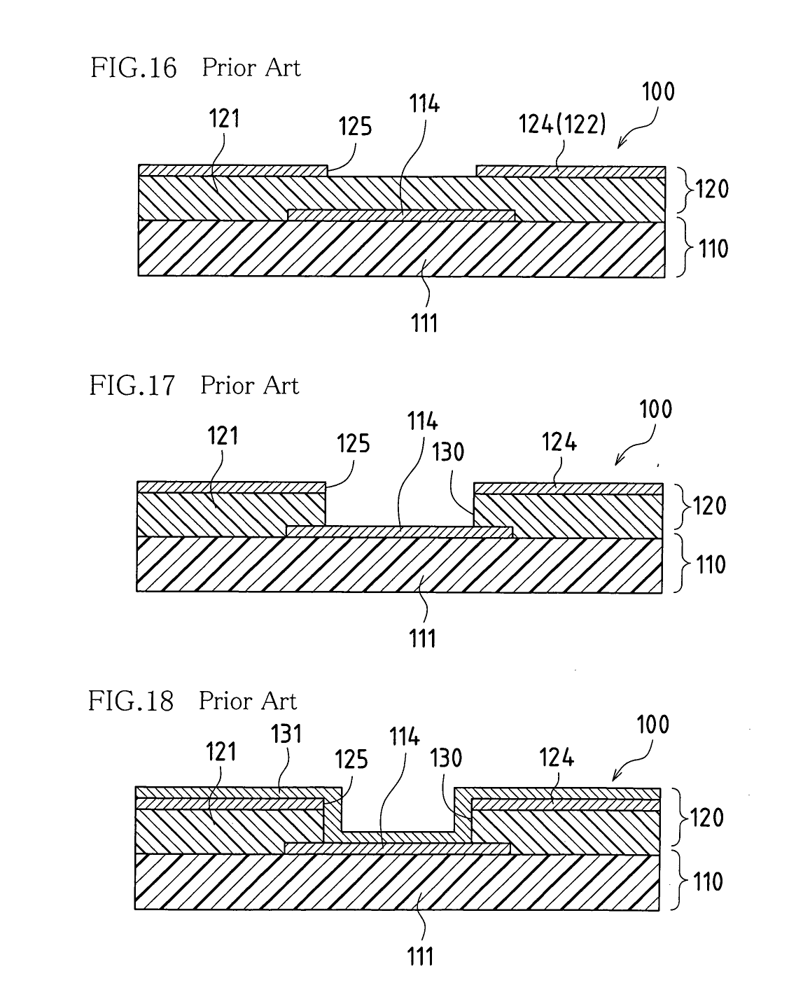

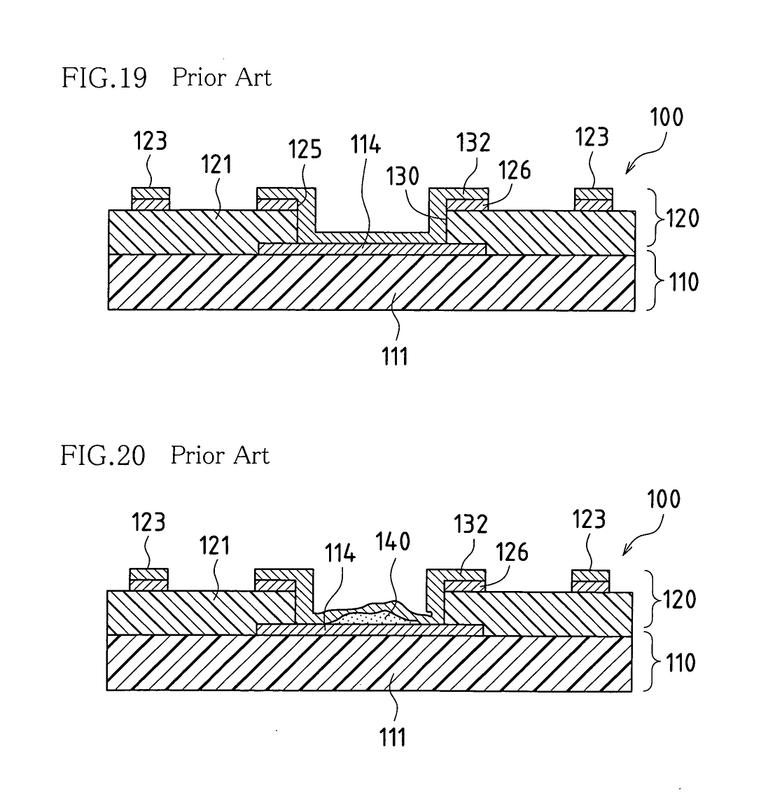

FIG. 12 shows a state in which laser processing was performed by more precisely controlling adjustment of the position of the bottom face of the via hole.

In the present example, as in the case of FIG. 11, the inner insulating resin layer 11 is formed from a resin layer for which laser processing is difficult, and a resin layer for which laser processing is easy, disposed between the resin layer for which laser processing is difficult and the inner via land 14.

Ordinarily, the inner insulating resin layer 11 is constituted from fiberglass-reinforced epoxy, but the fiberglass in an outside inner insulating resin layer 11b near the outer insulating resin layer 21 is formed (adjusted) with fine fiber or a course weave, and conversely, an inside inner insulating resin layer 11a far from the outer insulating resin layer 21 is formed (adjusted) with thick fiber or a fine weave.

With this configuration, when performing laser processing, processing of the via hole 30 finishes at the position of the inside inner insulating resin layer 11a, and the bottom face is decided.

FIG. 13 shows a state in a multilayer printed circuit board configured such that an edge face of an inner window portion is exposed to a side face of the via hole.

In the present example, by making the size of the inner periphery of the inner window portion 15 formed in the inner via land 14 approximately the same as the size of the inner periphery of the outer window portion 25 formed in the outer via land layer 24, the inner via land 14 is configured such that only an edge face of the inner window portion 15 is exposed to a side face (wall face) of the via hole 30. That is, the edge face of the inner window portion 15 and the via land connecting portion 32 are connected only at the side face of the via hole 30, and so it is not necessary to consider residual material 40 formed on the bottom face of the via hole 30.

This structure has the same connecting structure as an ordinary through-hole or the like, and by appropriately adjusting the depth of the hole, it is possible to realize an interlayer connection with high reliability.

The present invention may be embodied in various other forms without departing from the gist or essential characteristics thereof. The embodiments disclosed in this application are to be considered in all respects as illustrative and not limiting. The scope of the invention is indicated by the appended claims rather than by the foregoing description, and all modifications or changes that come within the meaning and range of equivalency of the claims are intended to be embraced therein.

1. A fabrication method for a multilayer printed wiring board, comprising:
forming an inner via land on the surface of an inner insulating resin layer, and layering an outer insulating resin layer that covers the inner via land on the inner insulating resin layer, and forming an outer via land layer having an outer window portion whose position is matched to that of the inner via land on the surface of the outer insulating resin layer, and forming a via hole that exposes the inner via land by removing the outer insulating resin layer that corresponds to the outer window portion using the outer via land layer as a mask, and forming an interlayer connecting layer that connects the exposed inner via land and the outer via land layer, wherein
when forming the inner via land, an inner window portion that passes through the inner via land is formed, and
the via hole is formed by laser processing.

2. The fabrication method for a multilayer printed wiring board according to claim 1, wherein a bottom face of the via hole is positioned in the inner window portion.

3. The fabrication method for a multilayer printed wiring board according to claim 1, wherein the bottom face of the via hole is positioned in the inner insulating resin layer.

4. The fabrication method for a multilayer printed wiring board according to claim 1, wherein a flat face of the inner via land is exposed to the bottom face of the via hole.

5. The fabrication method for a multilayer printed wiring board according to claim 1, wherein an edge face of the inner window portion is exposed to a side face of the via hole.

6. The fabrication method for a multilayer printed wiring board according to claim 1, wherein an inner circuit pattern is formed when forming the inner via land.

7. The fabrication method for a multilayer printed wiring board according to claim 1, wherein the inner insulating resin layer and the outer insulating resin layer are formed from epoxy resin, polyimide resin, polyether ketone resin, polyester resin, or liquid crystal polymer resin.

8. The fabrication method for a multilayer printed wiring board according to claim 7, wherein the inner insulating resin layer and the outer insulating resin layer include fiber cloth or nonwoven cloth.

9. The fabrication method for a multilayer printed wiring board according to claim 1, wherein the laser processing is performed with a carbon dioxide gas laser or a YAG laser.

10. A fabrication method for a multilayer printed wiring board in which the processes in claim 1 are repeated.

11. A multilayer printed wiring board, comprising:
an inner insulating resin layer,
an inner via land formed on the surface of the inner insulating resin layer, an outer insulating resin layer that covers the inner via land on the inner insulating resin layer, an outer via land having an outer window portion whose position is matched to that of the inner via land formed on the surface of the outer insulating resin layer, a via hole formed such that it corresponds to the outer window portion and passes through the outer insulating resin layer, and a via land connecting portion that is formed in the via hole and connects the outer via land and the inner via land, wherein
the inner via land has an inner window portion that passes through the inner via land.

12. The multilayer printed wiring board according to claim 11, wherein the processing speed with laser processing is slower for the inner insulating resin layer than for the outer insulating resin layer.

13. The multilayer printed wiring board according to claim 11, wherein the inner insulating resin layer includes a resin layer for which laser processing is difficult, and a resin layer for which laser processing is easy, formed between the resin layer for which laser processing is difficult and the inner via land.

14. The multilayer printed wiring board according to claim 13, wherein the resin layer for which laser processing is difficult and the resin layer for which laser processing is easy include reinforced fiber, and the density of the reinforced fiber is larger for the resin layer for which laser processing is difficult than for the resin layer for which laser processing is easy.

15. The multilayer printed wiring board according to claim 14, wherein the density of the reinforced fiber is adjusted by the area of openings in the weave of the reinforced fiber.

16. The multilayer printed wiring board according to claim 14, wherein the density of the reinforced fiber is adjusted by the thickness of the reinforced fiber.

17. The multilayer printed wiring board according to claim 13, wherein the resin layer for which processing is difficult includes reinforced fiber, and the resin layer for which processing is easy does not include reinforced fiber.

18. The multilayer printed wiring board according to claim 11, wherein the inner insulating resin layer has a metal foil layer at an inside position that corresponds to the inner window portion, and a flat face of the metal foil layer is exposed to the bottom face of the via hole.

19. The multilayer printed wiring board according to claim 11, wherein the inner insulating resin layer has a concave portion corresponding to the inner window portion.

20. The multilayer printed wiring board according to claim 11, wherein an edge face of the inner window portion is exposed to a side face of the via hole, and the edge face and the via land connecting portion are connected.
